(19) United States
(12) Patent Application Publication
(10) Pub. No.: US 2013/0119507 A1
(43) Pub. Date: May 16, 2013

(54) SEMICONDUCTOR DEVICE USING GROUP III-V MATERIAL AND METHOD OF MANUFACTURING THE SAME

(71) Applicants: Sang-moon LEE, Yongin-si (KR); Young-jin CHO, Yongin-si (KR)

(72) Inventors: Sang-moon LEE, Yongin-si (KR); Young-jin CHO, Yongin-si (KR)

(73) Assignee: SAMSUNG ELECTRONICS CO., LTD., Suwon-si (KR)

(21) Appl. No.: 13/614,303

(22) Filed: Sep. 13, 2012

(30) Foreign Application Priority Data
Nov. 16, 2011 (KR) 10-2011-0119778

(51) Int. Cl. H01L 21/762; H01L 21/8234; H01L 27/00

(52) U.S. Cl. 257/506; 438/404; 438/151; 438/152; 257/E27.001; 257/E21.561; 257/E21.616

(57) ABSTRACT

Semiconductor devices using a group III-V material, and methods of manufacturing the same, include a substrate having a groove, a group III-V material layer filling in the groove and having a height the same as a height of the substrate, a first semiconductor device on the group III-V material layer, and a second semiconductor device on the substrate near the groove. The group III-V material layer is spaced apart from inner side surfaces of the groove.

### CROSS-REFERENCE TO RELATED APPLICATIONS

This application claims the benefit of priority from Korean Patent Application No. 10-2011-0119778, filed on Nov. 16, 2011, in the Korean Intellectual Property Office, the disclosure of which is incorporated herein by reference in its entirety.

### BACKGROUND

1. Field

Example embodiments relate to semiconductor devices and methods of manufacturing the same, and more particularly, to semiconductor devices using a group III-V material and methods of manufacturing the same.

2. Description of the Related Art

As semiconductor devices are highly integrated, the sizes of and the distances between elements of a semiconductor device are reduced. For example, in a silicon (Si)-based transistor, the sizes of and the distances between source, drain, and gate electrodes are reduced. Because the size of the gate electrode is reduced, the length of a channel is also reduced and thus characteristics of the transistor deteriorate due to the short channel effect. In order to cope with the restriction in size of the gate electrode, a method of replacing a channel material with a group III-V material is suggested.

However, due to a difference in crystal constant and thermal conductivity between a group III-V material and Si, a large number of defects are formed on an interface between the two materials. As such, device applications are limited.

Also, when a Si-based semiconductor device and a group III-V material-based semiconductor device are combined, difficulties may occur due to a step between a substrate for forming the Si-based semiconductor device and a substrate for forming the group III-V material-based semiconductor device.

### SUMMARY

Example embodiments relate to semiconductor devices and methods of manufacturing the same, and more particularly, to semiconductor devices using a group III-V material and methods of manufacturing the same.

Provided are semiconductor devices using a group III-V material, capable of reducing defects on a device forming part of a group III-V material layer and a step between two neighboring semiconductor devices.

Provided are methods of manufacturing the semiconductor devices.

Additional aspects will be set forth in part in the description which follows and, in part, will be apparent from the description, or may be learned by practice of the presented embodiments.

According to example embodiments, a semiconductor device includes a substrate having a groove, a group III-V material layer filling in the groove and having a height the same as a height of the substrate, a first semiconductor device on the group III-V material layer, and a second semiconductor device on the substrate near the groove, wherein the group III-V material layer is spaced apart from inner side surfaces of the groove.

The first semiconductor device may be one selected from the group consisting of a first transistor, a light emitting diode (LED), a laser diode (LD), and a solar cell.

The second semiconductor device may be a second transistor.

The semiconductor device may further include an insulating layer between the inner side surfaces of the groove and the group III-V material layer.

The group III-V material layer may be one selected from a binary material layer, a ternary material layer, and a quaternary material layer, and the group III-V material layer may include at least one group III element and at least one group V element.

The groove may have an aspect ratio of 0.1 to 3.

The insulating layer may include one selected from the group consisting of silicon oxide, silicon nitride, and aluminum oxide.

According to other example embodiments, a method of manufacturing a semiconductor device includes forming a groove in a substrate, forming an insulating layer on inner side surfaces of the groove, growing a group III-V material layer in the groove to a height the same as a height of the substrate, forming a first semiconductor device on the group III-V material layer, and forming a second semiconductor device on the substrate near the groove.

The forming of the insulating layer may include forming the insulating layer on the substrate so as to cover the inner side surfaces and a bottom surface of the groove, and removing the insulating layer from the bottom surface of the groove.

The group III-V material layer may be one selected from the group consisting of a binary material layer, a ternary material layer, and a quaternary material layer, and the group III-V material layer may include at least one group III element and at least one group V element.

The groove may have an aspect ratio of 0.1 to 3.

The insulating layer may include one selected from silicon oxide, silicon nitride, and aluminum oxide.

The forming of the first semiconductor device may include sequentially stacking a first gate insulating layer and a first gate electrode on a first partial region of the group III-V material layer; and forming a first impurity region and a second impurity region in the group III-V material layer at opposing sides of the first gate electrode.

The growing of the group III-V material layer may include doping a material having a type opposite to a type of a doping material of the substrate.

The forming of the second semiconductor device may include sequentially stacking a second gate insulating layer and a second gate electrode on a second partial region of the substrate; and forming a third impurity region and a fourth impurity region in the substrate at opposing sides the second gate electrode.

The first semiconductor device may be one selected from the group consisting of a light emitting diode (LED), a laser diode (LD), and a solar cell.

Some elements of the first and second semiconductor devices may be simultaneously formed.

The method may further include providing a mask over the substrate outside the groove. The mask may be used in the forming of the first semiconductor device.

The method may further include providing a mask over the groove. The groove may be masked when the second semiconductor device is formed.

A semiconductor device according to example embodiments is formed by forming a groove in a substrate to have a certain aspect ratio, forming a mask (e.g., an insulating layer) on inner side surfaces of the groove, and forming a group III-V material layer (e.g., a compound semiconductor layer) on a selected region of a bottom surface of the groove. As such, defects may be limited to only a lower portion of the group III-V material layer and thus a larger portion of the group III-V material layer may be used as a high-quality region.

Also, because the group III-V material layer ultimately has a height the same as the height of the substrate around the group III-V material layer, problems caused by a step in a manufacturing process of the semiconductor device may be prevented.

### BRIEF DESCRIPTION OF THE DRAWINGS

These and/or other aspects will become apparent and more readily appreciated from the following description of the example embodiments, taken in conjunction with the accompanying drawings of which:

FIG. 1 is a cross-sectional view of a semiconductor device using a group III-V material, according to example embodiments; and

FIGS. 2 through 11 are sequential cross-sectional views for describing a method of manufacturing a semiconductor device using a group III-V material, according to example embodiments.

### DETAILED DESCRIPTION

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the invention.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to example embodiments described.

Example embodiments relate to semiconductor devices and methods of manufacturing the same, and more particularly, to semiconductor devices using a group III-V material and methods of manufacturing the same.

A semiconductor device using a group III-V material, according to an example embodiment of the present invention, will now be described.

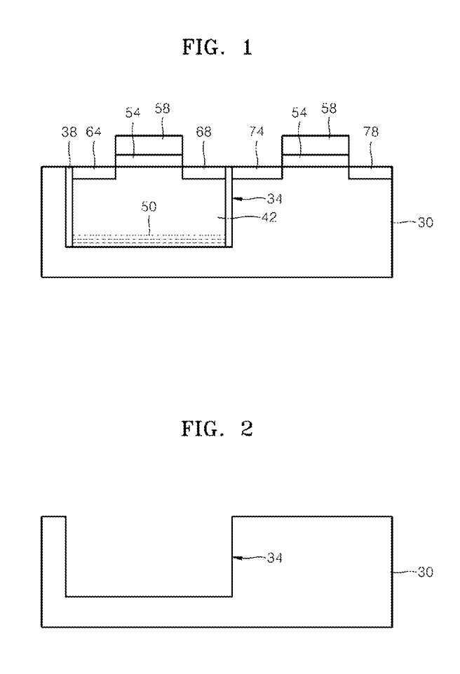

Referring to FIG. 1, a groove 34 having a set depth exists in a partial region of a substrate 30. The substrate 30 may be, for example, a silicon (Si) substrate. The groove 34 may have a set aspect ratio. The aspect ratio may be equal to, or greater than, 0.1 (e.g., 0.1 to 3.0). Inner side surfaces of the groove 34 are covered with an insulating layer 38. The insulating layer 38 may include, for example, silicon oxide (e.g., SiO₂), silicon nitride (e.g., SiNₓ), or aluminum oxide (e.g., Al₂O₃). The groove 34 covered with the insulating layer 38 is filled with a group III-V material layer 42. The group III-V material layer 42 includes defects 50 located near a bottom surface of the groove 34. The group III-V material layer 42 may include a doping material having a type opposite to the type of a doping material of the substrate 30. For example, if the substrate 30 includes an n-type doping material, the group III-V material layer 42 may include a p-type doping material, or vice versa. The group III-V material layer 42 may be a compound semiconductor layer including, for example, a binary, ternary, or quaternary material. The binary material may be, for example, GaAs, GaP, InP, InAs, GaSb, InSb, AlP, AlAs, or AlSb. The ternary or quaternary material may include, for example, at least one or two group III elements from among indium (In), gallium (Ga), and aluminum (Al), and at least one group V element from among arsenic (As), phosphorus (P), and antimony (Sb).

First and second impurity regions 64 and 68 exist in the group III-V material layer 42. The first and second impurity regions 64 and 68 may include a doping material having a type opposite to the type of the doping material of the group III-V material layer 42. The first and second impurity regions 64 and 68 are spaced apart from each other. One of the first and second impurity regions 64 and 68 may be a source region, and the other may be a drain region. The first and second impurity regions 64 and 68 may be spaced apart from the insulating layer 38.

A gate insulating layer 54 and a gate electrode 58 are sequentially stacked on the group III-V material layer 42 between the first and second impurity regions 64 and 68. The group III-V material layer 42 under the gate insulating layer 54 is used as a channel layer. The first and second impurity regions 64 and 68, the gate insulating layer 54, the gate electrode 58, and the group III-V material layer 42 may form an n-type or p-type first transistor. An n-type or p-type second transistor (30+54+58+74+78) exists on the substrate 30 and outside the groove 34. The second transistor (30+54+58+74+78) has a type opposite to the type of the first transistor. The first transistor and the second transistor (30+54+58+74+78) may be combined to form a complementary metal oxide semiconductor (CMOS) device. A step does not occur between the group III-V material layer 42 and the substrate 30 on which the first transistor and the second transistor (30+54+58+74+78) are formed. Accordingly, processing problems caused by the step while the first transistor and the second transistor (30+54+58+74+78) are formed may be reduced or prevented. In the second transistor (30+54+58+74+78), third and fourth impurity regions 74 and 78 exist in the substrate 30. The third and fourth impurity regions 74 and 78 are spaced apart from each other. The third and fourth impurity regions 74 and 78 may include a doping material having a type opposite to the type of the doping material of the substrate 30. One of the third and fourth impurity regions 74 and 78 may be a source region, and the other may be a drain region. The gate insulating layer 54 and the gate electrode 58 exist on the substrate 30 between the third and fourth impurity regions 74 and 78.

Instead of the first transistor, another semiconductor or optical device may be formed on the group III-V material layer 42 filled in the groove 34. For example, the group III-V material layer 42 may be used as a base substrate, and a light emitting diode (LED), a laser diode (LD), or a solar cell may be formed on the base substrate.

A method of manufacturing a semiconductor device using a group III-V material, according to example embodiments, will now be described with reference to FIGS. 2 through 11.

In this case, like reference numerals refer to like elements between FIG. 1 and FIGS. 2 through 11, and descriptions thereof will not be provided here.

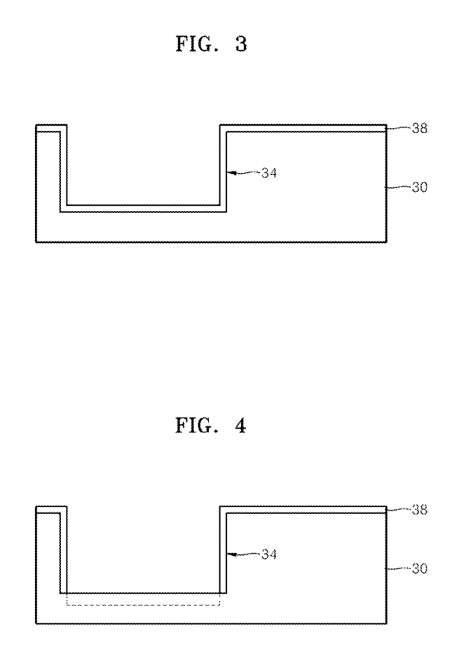

Referring to FIG. 2, the groove 34 is formed in the substrate 30. Then, as illustrated in FIG. 3, the insulating layer 38 is formed on the substrate 30 so as to cover internal surfaces (i.e., inner side surfaces and a bottom surface) of the groove 34.

Then, as illustrated in FIG. 4, the insulating layer 38 is removed from the bottom surface of the groove 34 so as to expose the bottom surface of the groove 34. The insulating layer 38 formed on the bottom surface of the groove 34 may be removed by using a dry anisotropic etching method. In this process, the outside of the groove 34 may be protected by using a mask (not shown) such as a photoresist pattern.

Referring to FIG. 4, after the insulating layer 38 is removed from the bottom surface of the groove 34, a recess (a dashed line region) may be further formed in the bottom surface of the groove 34 of the substrate 30 by further etching the exposed portion of the substrate 30. By forming the recess, the defects 50 of the group III-V material layer 42 to be formed in a subsequent process may be limited into the recess, and thus the group III-V material layer 42 may have a larger high-quality region.

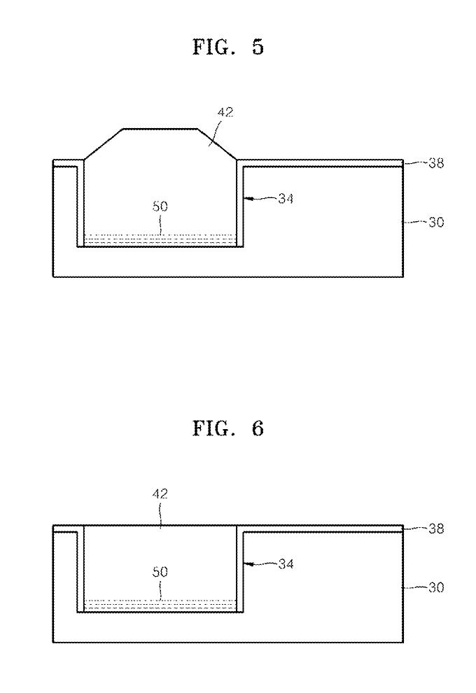

Then, referring to FIG. 5, the group III-V material layer 42 is selectively formed on the bottom surface of the groove 34 (i.e., the exposed region of the substrate 30). In this case, because the inner side surfaces of the groove 34 are covered with the insulating layer 38, the defects 50 of the group III-V material layer 42 are limited to a lower portion of the group III-V material layer 42. That is, the defects 50 exist near the bottom surface of the groove 34. As such, an upper portion of the group III-V material layer 42 may be a high-quality group III-V material layer. The group III-V material layer 42 may fill the groove 34 and may protrude from an upper surface of the substrate 30. The group III-V material layer 42 may grow by using an epitaxial method. As described above in relation to FIG. 4, if the recess (the dashed line region) exists in the bottom surface of the groove 34, the group III-V material layer 42 may also grow by using a lateral growth method. As illustrated in FIG. 6, the protruding part of the group III-V material layer 42 on the groove 34 is removed to planarize the group III-V material layer 42. The protruding part of the group III-V material layer 42 on the groove 34 may be removed by using, for example, chemical mechanical polishing (CMP) method. In this case, CMP may be performed until the insulating layer 38 is exposed.

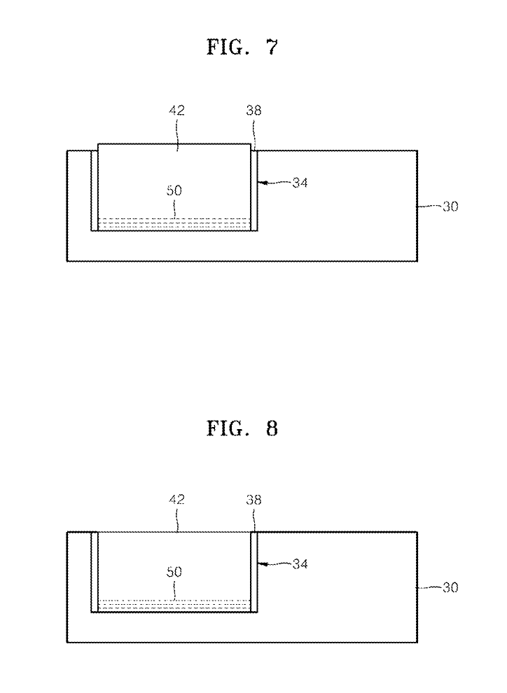

Then, referring to FIGS. 6 and 7, the insulating layer 38 is removed from the upper surface of the substrate 30. Then, as illustrated in FIG. 8, an upper surface of the group III-V material layer 42 is polished to have a height the same as the height of the substrate 30.

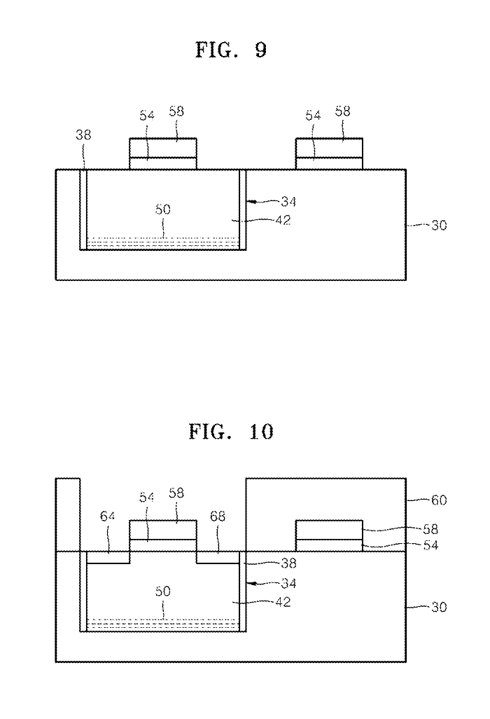

Then, referring to FIG. 9, the gate insulating layer 54 and the gate electrode 58 are sequentially stacked on a partial region of the group III-V material layer 42. In this case, the gate insulating layer 54 and the gate electrode 58 are also sequentially stacked on a partial region of the upper surface of the substrate 30.

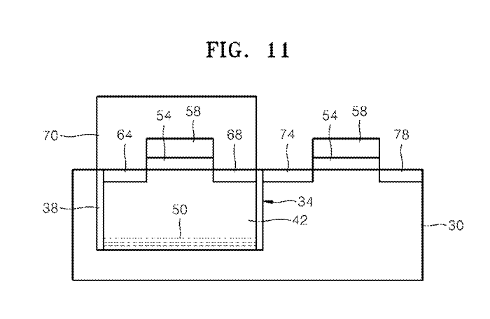

Then, as illustrated in FIG. 10, a mask 60 for covering the outside of the groove 34 is formed on the substrate 30. As such, the gate insulating layer 54 and the gate electrode 58 formed on the group III-V material layer 42 are exposed.

Referring to FIG. 10, after the mask 60 is formed, the first and second impurity regions 64 and 68 are formed by ion-injecting a first conductive impurity into the group III-V material layer 42 at two sides of the gate electrode 58. In this case, the first conductive impurity may be an n-type or p-type impurity and may have a type opposite to the type of a doping material of the group III-V material layer 42. As such, an n-type or p-type first transistor is formed on the group III-V material layer 42. After that, the mask 60 is removed.

Then, referring to FIG. 11, a mask 70 for covering the first transistor formed on the group III-V material layer 42 is formed. After the mask 70 is formed, the third and fourth impurity regions 74 and 78 are formed in the substrate 30 at two sides of the gate electrode 58 by ion-injecting a second conductive impurity into the substrate 30. The second conductive impurity may be an n-type or p-type impurity, may have a type opposite to the type of the first conductive impurity, and may have a type opposite to the type of a doping material of the substrate 30. As such, an n-type or p-type second transistor having a type opposite to the type of the first transistor is formed on the substrate 30. After that, the mask 70 is removed. The first and second transistors may be electrically connected to form a CMOS device.

Meanwhile, instead of the first transistor, an LED, an LD, or a solar cell may be formed on the group III-V material layer 42 filled in the groove 34.

It should be understood that the example embodiments described therein should be considered in a descriptive sense only and not for purposes of limitation. Descriptions of features or aspects within each example embodiment should typically be considered as available for other similar features or aspects in other example embodiments.

What is claimed is:

1. A semiconductor device, comprising:
a substrate having a groove;
a group III-V material layer filling in the groove and having a height the same as a height of the substrate;
a first semiconductor device on the group III-V material layer; and
a second semiconductor device on the substrate near the groove,
wherein the group III-V material layer is spaced apart from inner side surfaces of the groove.

2. The semiconductor device of claim 1, wherein the first semiconductor device is one selected from the group consisting of a first transistor, a light emitting diode (LED), a laser diode (LD), and a solar cell.

3. The semiconductor device of claim 2, wherein the second semiconductor device is a second transistor.

4. The semiconductor device of claim 1, further comprising an insulating layer between the inner side surfaces of the groove and the group III-V material layer.

5. The semiconductor device of claim 1, wherein,
the group III-V material layer is one selected from the group consisting of a binary material layer, a ternary material layer, and a quaternary material layer, and
the group III-V material layer includes at least one group III element and at least one group V element.

6. The semiconductor device of claim 1, wherein the groove has an aspect ratio of 0.1 to 3.

7. The semiconductor device of claim 4, wherein the insulating layer includes one selected from the group consisting of silicon oxide, silicon nitride, and aluminum oxide.

8. A method of manufacturing a semiconductor device, the method comprising:
forming a groove in a substrate;
forming an insulating layer on inner side surfaces of the groove;
growing a group III-V material layer in the groove to a height the same as a height of the substrate;
forming a first semiconductor device on the group III-V material layer; and
forming a second semiconductor device on the substrate near the groove.

9. The method of claim 8, wherein the forming of the insulating layer includes,
forming the insulating layer on the substrate so as to cover the inner side surfaces and a bottom surface of the groove; and
removing the insulating layer from the bottom surface of the groove.

10. The method of claim 8, wherein,
the group III-V material layer is one selected from a binary material layer, a ternary material layer, and quaternary material layer, and
the group III-V material layer includes at least one group III element and at least one group V element.

11. The method of claim 8, wherein the groove has an aspect ratio of 0.1 to 3.

12. The method of claim 8, wherein the insulating layer includes one selected from silicon oxide, silicon nitride, and aluminum oxide.

13. The method of claim 8, wherein the forming of the first semiconductor device includes,
sequentially stacking a first gate insulating layer and a first gate electrode on a first partial region of the group III-V material layer; and
forming a first impurity region and a second impurity region in the group III-V material layer at opposing sides of the first gate electrode.

14. The method of claim 8, wherein the growing of the group III-V material layer includes doping a material having a type opposite to a type of a doping material of the substrate.

15. The method of claim 13, wherein the forming of the second semiconductor device includes,
sequentially stacking a second gate insulating layer and a second gate electrode on a second partial region of the substrate; and
forming a third impurity region and a fourth impurity region in the substrate at opposing sides the second gate electrode.

16. The method of claim 8, wherein the first semiconductor device is one selected from the group consisting of a light emitting diode (LED), a laser diode (LD), and a solar cell.

17. The method of claim 8, wherein some elements of the first and second semiconductor devices are simultaneously formed.

18. The method of claim 8, further comprising providing a mask over the substrate outside the groove, wherein the mask is used in the forming of the first semiconductor device.

19. The method of claim 8, further comprising providing a mask over the groove, wherein the mask is used in the forming of the second semiconductor device.
